(19) United States
(12) Patent Application Publication
(10) Pub. No.: US 2022/0122951 A1
(43) Pub. Date: Apr. 21, 2022

(54) PACKAGING STRUCTURE AND METHOD FOR MANUFACTURING PACKAGING STRUCTURE

(71) Applicant: SOCLE TECHNOLOGY CORP., Hsinchu (TW)

(72) Inventors: CHING-YU NI, New Taipei (TW); HSIANG-HUA LU, New Taipei (TW)

(21) Appl. No.: 17/095,618

(22) Filed: Nov. 11, 2020

(30) Foreign Application Priority Data
Oct. 16, 2020 (CN) 202011111054.7

(51) Int. Cl. H01L 25/10; H01L 23/00; H01L 23/31; H01L 23/538; H01L 21/48; H01L 21/56; H01L 25/00

(52) U.S. Cl. CPC H01L 25/105; H01L 24/20; H01L 23/3128; H01L 23/5383; H01L 23/5386; H01L 23/5389; H01L 2224/214; H01L 21/4857; H01L 21/565; H01L 24/19; H01L 25/50; H01L 2225/1035; H01L 2225/1058; H01L 21/4853

(57) ABSTRACT

Packaging structure includes a first packaging component and a second packaging component arranged in the first packaging component. The packaging component includes a first substrate, a first redistribution layer, a first electronic component, and a first packaging body. The first redistribution layer is arranged on the first substrate. The first electronic component is arranged on the first redistribution layer and electrically coupled to the first redistribution layer. The first packaging body is arranged on the first substrate and covers the first electronic component. The second packaging component includes a second substrate, a second redistribution layer, a second electronic component, and a second packaging body. The redistribution layer is arranged on the second substrate and electrically coupled to the first redistribution layer. The second electronic component is arranged on the second redistribution layer and electrically coupled to the second redistribution layer. The second packaging body covers the second electronic component.

### FIELD

The subject matter herein generally relates to a packaging structure and a method for manufacturing the packaging structure.

### BACKGROUND

With the continuous advancement of technology, miniaturization of electronic products is desired. Therefore, a packaging structure with high integration, multi-functionality, and miniaturization to meet the trend of miniaturization of electronic products is desired.

### BRIEF DESCRIPTION OF THE DRAWINGS

Implementations of the present disclosure will now be described, by way of embodiments, with reference to the attached figures.

FIG. 1 is a schematic cross-sectional view of a packaging structure according to an embodiment.

FIG. 2 is a schematic partial cross-sectional view of a first packaging component shown in FIG. 1.

FIG. 3 is a schematic partial cross-sectional view of the packaging structure shown in FIG. 1.

FIG. 4 is a schematic partial cross-sectional view of a second packaging component shown in FIG. 1.

FIG. 5 is a schematic cross-sectional view of the second packaging component shown in FIG. 1.

FIG. 6 is a schematic partial cross-sectional view of the packaging structure shown in FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

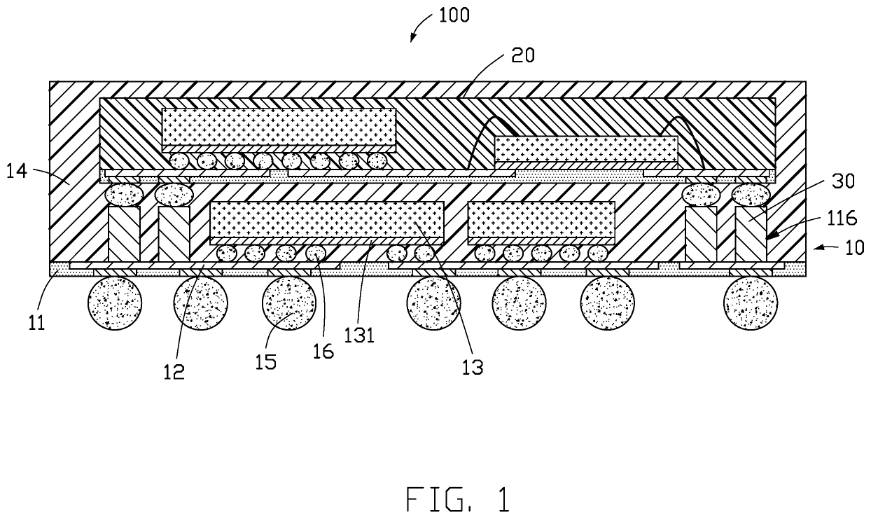

FIG. 1 shows an embodiment of a packaging structure 100. The packaging structure 100 includes a first packaging component 10 and a second packaging component 20.

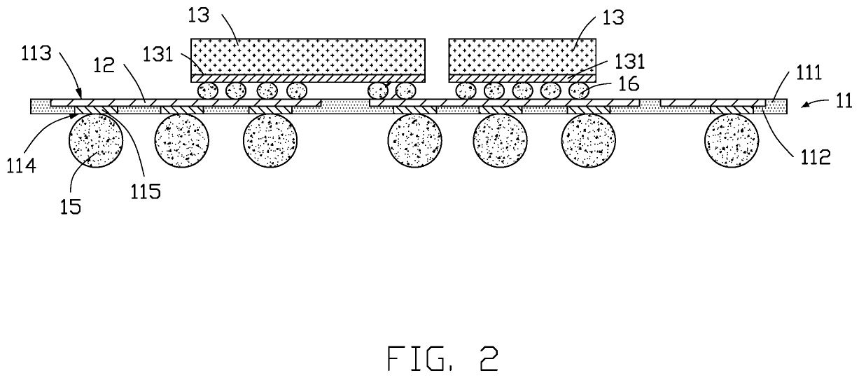

Referring to FIG. 2, the first packaging component 10 includes a first substrate 11, a first redistribution layer (RDL) 12, at least one first electronic component 13, and a first packaging body 14.

The first substrate 11 is used to provide support and includes a first surface 111 and a second surface 112 opposite to the first surface 111. The first substrate 11 may be a ceramic substrate, a glass substrate, or a polymer substrate.

The first redistribution layer 12 is arranged on the first surface 111. The first redistribution layer 12 may be a single-layer or multi-layer structure. The first redistribution layer 12 may be made of dielectric materials and/or conductive materials and may be formed on the first surface 111 by processes such as deposition, inlaying, electroplating, or chemical plating.

In one embodiment, the first surface 111 is provided with a first receiving groove 113. The first redistribution layer 12 is arranged in the first receiving groove 113 to reduce a required thickness of the packaging structure 100. The first packaging component 10 includes a plurality of first redistribution layers 12. Correspondingly, the first surface 111 is provided with a plurality of the first receiving grooves 113 for correspondingly receiving the plurality of first redistribution layers 12.

A first electrical connector 115 is provided on the second surface 112. The first electrical connector 115 is electrically coupled to the first redistribution layer 12. In one embodiment, the second surface 112 is provided with a second receiving groove 114. The first electrical connector 115 is arranged in the second receiving groove 114 to reduce a required thickness of the packaging structure 100. The second receiving groove 114 communicated with a corresponding first receiving groove 113, so that the first electrical connector 115 and the first redistribution layer 12 are electrically coupled.

In one embodiment, the first electrical connector 115 is provided with a first electrical connection body 15. The first electrical connection body 15 may be a metal pad, a stud, a conductive pillar, a solder ball, or another component that performs electrical connection. The material of the first electrical connection body 15 can be, but is not limited to, copper, aluminum, tungsten, gold, silver, nickel, and their alloys. In one embodiment, the first electrical connection body 15 is a solder ball. The first electrical connection body 15 can be formed by a ball mounting process.

The at least one first electronic component 13 is arranged on the first redistribution layer 12 and electrically coupled to the first redistribution layer 12. The first electronic component 13 may be an integrated circuit (IC) chip, a memory chip, a logic circuit, an antenna, or a wireless transceiver, or may be a passive device such as a resistor.

In one embodiment, each first electronic component 13 is provided with a first contact 131 facing a surface of the first substrate 11. Each first electronic component 13 is electrically coupled to the first redistribution layer 12 through the first contact 131. The first contact 131 may be, but is not limited to, copper, aluminum, tungsten, tin, nickel, gold, silver, or another conductive material. The first contact 131 may be formed by processes such as electroplating, sputtering, and the like.

The first packaging component 10 further includes a second electrical connection body 16. The second electrical connection body 16 is arranged between the first contact 131 and the first redistribution layer 12, so that the at least one first electronic component 13 and the first redistribution layer 12 are electrically coupled together. The second electrical connection body 16 may be a metal pad, a stud, a conductive pillar, a solder ball, or another component that performs electrical connection. The material of the second electrical connection body 16 can be, but is not limited to, copper, aluminum, tungsten, gold, silver, nickel, and their alloys. In one embodiment, the second electrical connection body 16 is a solder ball. The second electrical connection body 16 can be formed by a ball mounting process.

Referring to FIG. 1, the first packaging body 14 covers the at least one first electronic component 13, the first contact 131, and the second electrical connection body 16, and is arranged on the first surface 111 of the first substrate 11. The material of the first packaging body 14 may be a non-conductive material. The non-conductive material may include one or more of epoxy molding compound (EMC), acrylonitrile butadiene styrene (ABS), polycarbonate (PC), polyethylene terephthalate (PET), and other injection molding materials one or more.

Referring to FIGS. 1, 4, and 5, the second packaging component 20 is arranged in the first packaging body 14 and above the at least one first electronic component 13. In one embodiment, the second packaging component 20 includes a second substrate 21, a second redistribution layer 22, at least one second electronic component 23, and a second packaging body 24.

The second substrate 21 is used to provide support and includes a third surface 211 and a fourth surface 212 opposite to the third surface 211. The second substrate 21 may be a ceramic substrate, a glass substrate, or a polymer substrate.

The second redistribution layer 22 is arranged on the third surface 211. The second redistribution layer 22 may be a single-layer or multi-layer structure. The second redistribution layer 22 may be made of dielectric materials and/or conductive materials, and may be formed on the third surface 211 by processes such as deposition, inlaying, electroplating, or chemical plating.

In one embodiment, a third receiving groove 213 is provided on the third surface 211. The second redistribution layer 22 is received in the third receiving groove 213 to reduce a required thickness of the packaging structure 100. The second packaging component 20 includes a plurality of the second redistribution layers 22, and correspondingly, the third surface 211 is provided with a plurality of the first receiving grooves 213 for correspondingly receiving the plurality of second redistribution layers 22.

A second electrical connector 215 is provided on the fourth surface 212. The second electrical connector 215 is electrically coupled to the second redistribution layer 22. The second packaging component 20 is electrically coupled to the first redistribution layer 12 through the second electrical connector 215. In one embodiment, a fourth receiving groove 214 is provided on the fourth surface 212. The second electrical connector 215 is received in the fourth receiving groove 214 to reduce a required thickness of the packaging structure 100. The fourth receiving groove 214 communicated with the third receiving groove 213, so that the second electrical connector 215 and the second redistribution layer 22 are electrically coupled together.

In one embodiment, a third electrical connection body 25 is formed on the second electrical connector 215, so that the at least one second electronic component 23 is electrically coupled to the first redistribution layer 12 through the third electrical connector 25. The third electrical connection body 25 may be a metal pad, a stud, a conductive pillar, a solder ball, or another component that performs electrical connection. The material of the third electrical connection body 25 can be, but is not limited to, copper, aluminum, tungsten, gold, silver, nickel, and their alloys. In one embodiment, the third electrical connection body 25 is a solder ball. The third electrical connection body 25 can be formed by a ball mounting process.

The at least one second electronic component 23 is arranged on the second redistribution layer 22 and electrically coupled to the second redistribution layer 22. The second electronic component 23 may be an IC chip, a memory chip, a logic circuit, an antenna, or a wireless transceiver, or may be a passive device such as a resistor.

In one embodiment, each second electronic component 23 is provided with a second contact 231 facing a surface of the second substrate 21. Each second electronic component 23 is electrically coupled to the second redistribution layer 22 through the second contact 231. The material of the second contact 231 may be, but is not limited to, copper, aluminum, tungsten, tin, nickel, gold, silver, or another conductive material. The second contact 231 can be formed by processes such as electroplating, sputtering, and the like.

Further, a fourth electrical connection body 26 is provided between the second contact 231 and the second redistribution layer 22, so that the at least one second electronic component 23 is electrically coupled to the second redistribution layer 22. The fourth electrical connection body 26 may be a metal pad, a stud, a conductive post, a solder ball, or another component that can perform electrical connection. The material of the fourth electrical connection body 26 can be, but is not limited to, copper, aluminum, tungsten, gold, silver, nickel, and their alloys. In one embodiment, the fourth electrical connection body 26 is a solder ball. The fourth electrical connection body 26 can be formed by a ball mounting process.

In one embodiment, the at least one second electronic component 23 can be electrically coupled to the second redistribution layer 22 through a wire 232.

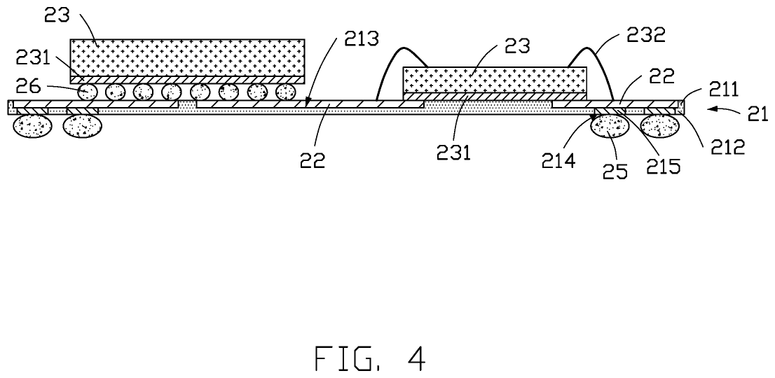

In another embodiment, the at least one second electronic component 23 can be electrically coupled to the second redistribution layer 22 through the wire 232 and the fourth electrical connection body 26 (shown in FIG. 4).

The second packaging body 24 covers the at least one second electronic component 23, the second contact 231, and the fourth electrical connector 26, and is arranged on the third surface 211 of the second substrate 21. The material of the second packaging body 24 may be a non-conductive material. The non-conductive material may include one or more of EMC, ABS, PC, PET, and other injection molding materials. In one embodiment, the second packaging body 24 completely covers the at least one second electronic component 23 to protect the second electronic component 23.

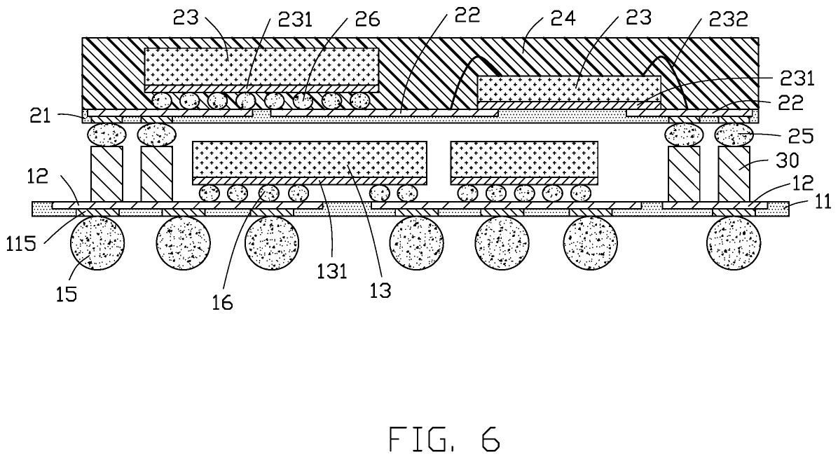

Referring to FIG. 1 and FIG. 6, the packaging structure 100 further includes a conductive member 30. The conductive member 30 may be a metal pad, a stud, a conductive column, a solder ball, or another component that performs electrical connection. The material of the conductive member 30 can be, but is not limited to, copper, aluminum, tungsten, gold, silver, nickel and their alloys.

Specifically, a surface of the first packaging body 14 facing the first substrate 11 is provided with a blind hole 116. The conductive member 30 is received in the blind hole 116 and electrically couples the first redistribution layer 12 and the second redistribution layer 22 together to serve as a transmission path between the first electronic component 13 and the second electronic component 23. In one embodiment, the conductive member 30 is arranged between the first redistribution layer 12 and the third electrical connection body 25.

This application further provides a method for manufacturing the packaging structure 100.

Referring to FIG. 2, the first substrate 11 is provided. The first substrate 11 includes the first surface 111 and the second surface 112 opposite to the first surface 111. The first substrate 11 may be a ceramic substrate, a glass substrate, or a polymer substrate.

The first redistribution layer 12 is formed on the first surface 111. The first redistribution layer 12 may be a single layer or a multilayer structure. The first redistribution layer 12 may be made of dielectric materials and/or conductive materials, and may be formed on the first surface 111 by processes such as deposition, inlaying, electroplating, or chemical plating. The number of the first redistribution layers 12 on the first surface 111 can be adjusted adaptively according to actual conditions.

In other embodiments, the first surface 111 is provided with the first receiving groove 113. The first redistribution layer 12 is received in the first receiving groove 113 to reduce the required thickness of the packaging structure 100. The first packaging component 10 includes a plurality of the first redistribution layers 12, and accordingly, the first surface 111 is provided with a plurality of the first receiving grooves 113 for correspondingly receiving the plurality of first redistribution layers 12.

The first electrical connector 115 is arranged on the second surface 112. The first electrical connector 115 is electrically coupled to the first redistribution layer 12. In one embodiment, the second surface 112 is provided with the second receiving groove 114. The first electrical connector 115 is received in the second receiving groove 114 to reduce the required thickness of the packaging structure 100. The second receiving groove 114 communicated with the first receiving groove 113, so that the first electrical connector 115 and the first redistribution layer 12 are electrically coupled together.

A first electrical connection body 15 is formed on the first electrical connector 115. The first electrical connection body 15 may be a metal pad, a stud, a conductive pillar, a solder ball, or another component that performs electrical connection. The material of the first electrical connection body 15 can be, but is not limited to, copper, aluminum, tungsten, gold, silver, nickel, and their alloys. In one embodiment, the first electrical connection body 15 is a solder ball. The first electrical connection body 15 can be formed by a ball mounting process.

The at least one first electronic component 13 is provided. The at least one first electronic component 13 is arranged on the first redistribution layer 12 and is electrically coupled to the first redistribution layer 12. The first electronic component 13 may be an IC chip, a memory chip, a logic circuit, an antenna, or a wireless transceiver, or may be a passive device such as a resistor. In one embodiment, two of the first electronic components 13 are provided. The two first electronic components 13 are arranged side-by-side and spaced apart. In other embodiments, the number of the first electronic components 13 can be adaptively adjusted according to actual needs.

In one embodiment, each first electronic component 13 is provided with the first contact 131 facing the surface of the first substrate 11. Each first electronic component 13 is electrically coupled to the first redistribution layer 12 through the first contact 131. The first contact 131 may be, but is not limited to, copper, aluminum, tungsten, tin, nickel, gold, silver, or another conductive material. The first contact 131 may be formed by processes such as electroplating, sputtering, and the like.

The second electrical connection body 16 is formed between the at least one first electronic component 13 and the first redistribution layer 12. The second electrical connection body 16 is arranged between the first redistribution layer 12 and the first contact 131. The at least one first electronic component 13 is electrically coupled to the first redistribution layer 12 through the first contact 131. The second electrical connection body 16 may be a metal pad, a stud, a conductive pillar, a solder ball, or another component that performs electrical connection. The second electrical connection body 16 can be, but is not limited to, copper, aluminum, tungsten, gold, silver, nickel, and their alloys. In one embodiment, the second electrical connection body 16 is a solder ball. The second electrical connection body 16 can be formed by a ball mounting process.

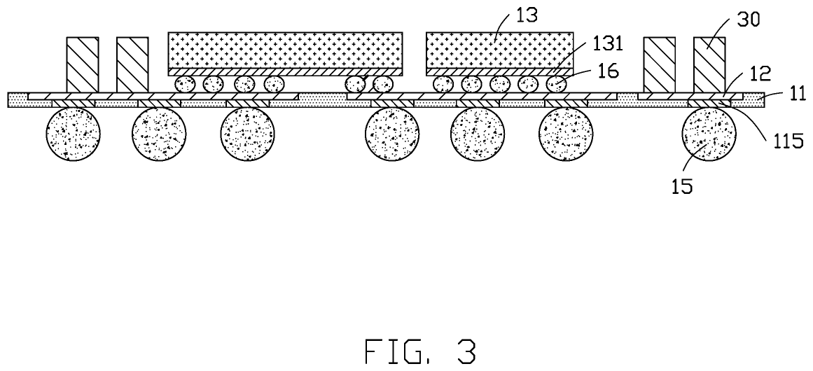

Referring to FIG. 3, the conductive member 30 is formed on the first redistribution layer 12. In one embodiment, the conductive member 30 is a copper pillar. The conductive member 30 can be formed by processes such as electroplating, sputtering, and the like.

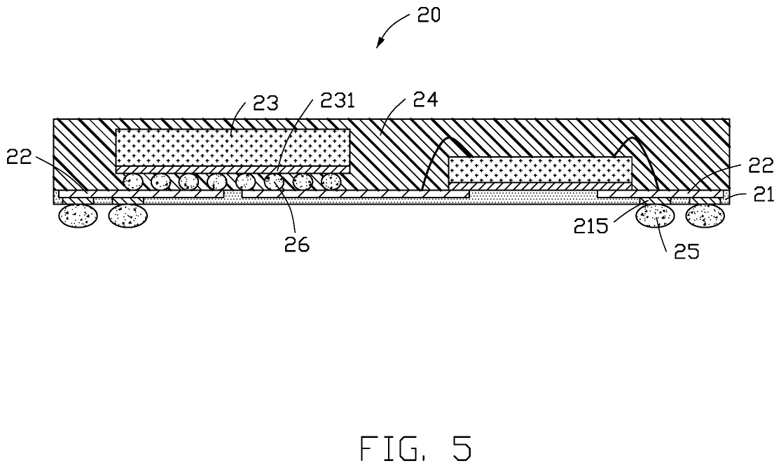

Referring to FIGS. 5 and 6, the second packaging component 20 as described above is provided. The third electrical connection body 25 is coupled to the conductive member 30.

Referring to FIG. 1, the first packaging body 14 is formed on the first substrate 11, and the first packaging body 14 covers the at least one first electronic component 13 and the second packaging component 20. The material of the first packaging body 14 may be a non-conductive material. The non-conductive material may include one or more of EMC, ABS, PC, PET, and other injection molding materials.

In summary, the second packaging component 20 in the packaging structure 100 is arranged in the first packaging component 10, so that the packaging structure 100 is highly integrated, and the thickness of the packaging structure 100 is reduced to adapt to the trend of miniaturization and integration of the packaging structure 100.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A packaging structure comprising:
a first packaging component comprising a first substrate, a first redistribution layer, at least one first electronic component, and a first packaging body, the first redistribution layer arranged on the first substrate, the at least one first electronic component arranged on the first redistribution layer and electrically coupled to the first redistribution layer, and the first packaging body arranged on the first substrate and covering the at least one first electronic component; and
a second packaging component arranged in the first packaging component, the second packaging component comprising a second substrate, a second redistribution layer, at least one second electronic component, and a second packaging body, the redistribution layer arranged on the second substrate and electrically coupled to the first redistribution layer, the at least one second electronic component arranged on the second redistribution layer and electrically coupled to the second redistribution layer, and the second packaging body covering the at least one second electronic component.

2. The packaging structure of claim 1, further comprising a conductive member, wherein:
the first packaging body is provided with a blind hole facing the first substrate;
the conductive member is received in the blind hole; and
the first redistribution layer and the second redistribution layer are electrically coupled through the conductive member.

3. The packaging structure of claim 2, wherein:
the conductive member is a metal pad, a stud, a conductive column, or a solder ball.

4. The packaging structure of claim 1, wherein:
each first electronic component is provided with a first contact;
each first electronic component is electrically coupled through the first contact to the first redistribution layer.

5. The packaging structure of claim 2, wherein:
each first electronic component is provided with a first contact;
each first electronic component is electrically coupled through the first contact to the first redistribution layer.

6. The packaging structure of claim 3, wherein:
each first electronic component is provided with a first contact;
each first electronic component is electrically coupled through the first contact to the first redistribution layer.

7. The packaging structure of claim 1, wherein:
the first packaging component comprises a plurality of the first redistribution layers; and
the at least one first electronic component is arranged on the plurality of first redistribution layers.

8. The packaging structure of claim 7, wherein:
the second packaging component comprises a plurality of the second redistribution layers; and
the at least one second electronic component is arranged on the plurality of second redistribution layers.

9. The packaging structure of claim 1, wherein:
the second packaging body completely covers the at least one second electronic component.

10. A method for manufacturing a packaging structure, the method comprising:
providing a first substrate;
forming a first redistribution layer on the first substrate;
providing at least one first electronic component, the at least one first electronic component arranged on the first redistribution layer and electrically coupled to the first redistribution layer;
providing a second packaging component comprising a second substrate, a second redistribution layer, at least one second electronic component, and a second packaging body, the second redistribution layer arranged on the second substrate and electrically coupled to the first redistribution layer, the at least one second electronic component arranged on the second redistribution layer and electrically coupled to the second redistribution layer, and the second packaging body covering the at least one second electronic component; and
forming a first packaging body on the first substrate, the first packaging body covering the at least one first electronic component and the second packaging component.

11. The manufacturing method of claim 10, further comprising:
after forming the first redistribution layer, forming a conductive member on the first redistribution layer, the conductive member electrically coupled to the first redistribution layer and the second redistribution layer.
